(19) United States
(12) Patent Application Publication
(10) Pub. No.: US 2025/0244389 A1
(43) Pub. Date: Jul. 31, 2025

(54) METHOD AND APPARATUS WITH BATTERY LIFE DETERMINATION

(71) Applicant: Samsung Electronics Co., Ltd., Suwon-si (KR)

(72) Inventors: Daeryong JUNG, Suwon-si (KR); Jinho KIM, Suwon-si (KR)

(73) Assignee: Samsung Electronics Co., Ltd., Suwon-si (KR)

(21) Appl. No.: 18/955,294

(22) Filed: Nov. 21, 2024

(30) Foreign Application Priority Data
Jan. 26, 2024 (KR) 10-2024-0012264

(51) Int. Cl. G01R 31/367; B60L 58/16; G01R 31/36; G01R 31/371; G01R 31/392; G01R 31/396

(52) U.S. Cl. CPC G01R 31/367; G01R 31/3648; G01R 31/371; G01R 31/392; G01R 31/396; B60L 58/16

(57) ABSTRACT

A processor-implemented method including updating a battery model indicating an internal state of a battery based on a first value set of one or more parameters indicating a state of the battery, determining a first cumulative degradation amount of the battery for the first value set, determining a first relation function based on the first value set and the first cumulative degradation amount, and determining a remaining useful life (RUL) of the battery based on the first relation function.

### CROSS-REFERENCE TO RELATED APPLICATIONS

This application claims the benefit under 35 USC § 119(a) of Korean Patent Application No. 10-2024-0012264, filed on Jan. 26, 2024, in the Korean Intellectual Property Office, the entire disclosure of which is incorporated herein by reference for all purposes.

### BACKGROUND

### 1. Field

The following description relates to a method and apparatus with battery (e.g., a lithium-ion battery) life determination.

### 2. Description of Related Art

When a lithium-ion battery is repeatedly charged and discharged, degradation occurs that reduces a capacity of the battery. A state of health (SOH) is most often used as a measure of a degree of battery degradation, and the SOH is generally defined as a ratio of a battery capacity when it is degraded compared to a battery capacity in a fresh state. Accurately estimating the SOH of a battery is important in several ways.

First, in order to use a battery safely and efficiently, it is important to estimate a state of charge (SOC) of the battery. When the battery is degraded, it is necessary to reflect the degree of battery degradation to an SOC estimation model to maintain SOC estimation accuracy. Accordingly, as the SOC estimation accuracy of the degraded battery increase, the SOH may be estimated more accurately.

Second, the SOH can be a key indicator about the potential for a long-term use of a battery. That is, if the SOH of the battery is below a specific value, the battery may be considered unusable. The state in which the battery is unusable may be called an end of life (EOL), and the EOL of the battery may depend on the purpose for which the battery is being used and thus, different values of a SOH (i.e., SOH 80%, SOH 70%, or SOH 60%) may be associated with the battery's EOL. In order to determine whether the state of the battery has reached the EOL, a current SOH of the battery may need to be determined.

For the long-term use of batteries, not only are technologies for estimating an SOH of a battery becoming prominent but also technologies that determine the remaining useful life (RUL) of a battery are also gaining prominence. The technology for estimating the RUL of a battery is a technology that estimates a capacity of the battery to be used until a state of the battery reaches an EOL from a current time point.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a processor-implemented method including updating a battery model indicating an internal state of a battery based on a first value set of one or more parameters indicating a state of the battery, determining a first cumulative degradation amount of the battery for the first value set, determining a first relation function based on the first value set and the first cumulative degradation amount, and determining a remaining useful life (RUL) of the battery based on the first relation function.

The determining of the first relation function may include determining a first difference set between a previous value set of the one or more parameters and the first value set and determining the first relation function based on the first difference set and the first cumulative degradation amount.

The determining of the first relation function may include determining the first relation function by updating a previous relation function determined based on a previous difference set determined before the first difference set and a previous cumulative degradation amount determined before the first cumulative degradation amount based on the first difference set and the first cumulative degradation amount.

The method may include determining a first state of health (SOH) of the battery for the first value set based on the battery model, and the determining of the RUL of the battery based on the first relation function may include, in response to a condition preset in association with the first SOH being satisfied, determining the RUL of the battery based on the first relation function.

The method may include receiving a request for calculating the RUL of the battery and the determining of the RUL of the battery based on the first relation function may include, in response to the request for calculating the RUL of the battery, determining the RUL of the battery based on the first relation function.

The determining of the RUL of the battery may include performing a first simulation on charging and discharging of the battery based on the battery model, determining a first predicted cumulative degradation amount of the battery based on a result of the first simulation, determining a first predicted value set of the one or more parameters based on the first relation function and the first predicted cumulative degradation amount, generating a battery prediction model by updating the battery model based on the first predicted value set, and determining the RUL of the battery based on the battery prediction model.

The first simulation may be a simulation based on a charging and discharging pattern for the battery.

The method may include generating the charging and discharging pattern based on a charge history and a discharge history of the battery.

The first simulation may be a simulation based on a standard charging and discharging pattern for the battery.

The method may include receiving the standard charging and discharging pattern from a server.

The method may include determining, using linear regression, a first gradient of a first straight line representing a plurality of first values of a first parameter within a first SOH section of the battery, determining a second gradient of a second straight line representing a plurality of second values of the first parameter within a second SOH section of the battery using linear regression, and determining a function type of the first relation function based on the first gradient and the second gradient.

The determining of the function type of the first relation function may include determining a first ratio of the second gradient to the first gradient and determining the function type of the first relation function based on the first ratio.

The method may include determining a second SOH of the battery based on the battery model and, in response to the second SOH corresponding to a preset limit SOH, providing a notification that the life of the battery has ended.

The battery may be included in a mobile terminal.

The battery may be included in a vehicle.

In a general aspect, here is provided a non-transitory computer-readable storage medium storing instructions that, when executed by a processor, cause the processor to perform the method.

In a general aspect, here is provided an electronic device including processors configured to execute instructions and a memory storing the instructions, wherein execution of the instructions configures the processors to update a battery model indicating an internal state of a battery based on a first value set of one or more parameters indicating a state of the battery, determine a first cumulative degradation amount of the battery for the first value set, determine a first relation function based on the first value set and the first cumulative degradation amount, and determine a remaining useful life (RUL) of the battery based on the first relation function.

The processors may be configured to determine a first difference set between a previous value set of the one or more parameters and the first value set and determine the first relation function based on the first difference set and the first cumulative degradation amount.

The processors may be configured to determine the first relation function by updating a previous relation function determined based on a previous difference set determined before the first difference set and a previous cumulative degradation amount determined before the first cumulative degradation amount based on the first difference set and the first cumulative degradation amount.

The processors may be configured to perform a first simulation on charging and discharging of the battery based on the battery model, determine a first predicted cumulative degradation amount of the battery as a result of the first simulation, determine a first predicted value set of the one or more parameters based on the first relation function and the first predicted cumulative degradation amount, generate a battery prediction model by updating the battery model based on the first predicted value set, and determine the RUL of the battery based on the battery prediction model.

In a general aspect, here is provided an electronic device included processors configured to execute instructions and a memory storing the instructions, wherein execution of the instructions configures the processors to update a battery model indicating an internal state of a battery based on a first value set of one or more parameters indicating a state of the battery and determine a remaining useful life (RUL) of the battery based on a determined a first cumulative degradation amount of the battery for the first value set and a determined first relation function based on the first value set and the first cumulative degradation amount.

### BRIEF DESCRIPTION OF THE DRAWINGS

FIG. 1 illustrates an example battery system according to one or more embodiments.

FIG. 2 illustrates an example electronic device according to one or more embodiments.

FIG. 3 illustrates an example method of determining a remaining useful life (RUL) of a battery according to one or more embodiments.

FIG. 4 illustrates an example method of determining a first relation function based on a first value set of one or more parameters and a first cumulative degradation amount according to one or more embodiments.

FIG. 5 illustrates an example method of determining a first relation function when a condition for a first state of health (SOH) of a battery is satisfied according to one or more embodiments.

FIG. 6A illustrates a correlation between an SOH of a battery and an anode surface resistance according to one or more embodiments.

FIG. 6B illustrates a correlation between an SOH of a battery and a reduction rate of a capacity of a cathode active material according to one or more embodiments.

FIG. 6C illustrates a correlation between an SOH of a battery and an electrode balance shift according to one or more embodiments.

FIG. 7 illustrates an example method of determining a function type of a first relation function according to one or more embodiments.

FIG. 8 illustrates an example method of determining a function type of a first relation function based on a first gradient and a second gradient according to one or more embodiments.

FIG. 9A illustrates an example of absolute values of a gradient that is determined for each of preset SOH sections, and shows a degree of a change of an anode surface resistance value for the corresponding SOH section, according to one or more embodiments.

FIG. 9B illustrates an example of ratios of a gradient a_{N} for a current SOH section to a gradient a_{N-1} for a previous SOH section based on gradients shown in FIG. 9A according to one or more embodiments.

FIG. 9C illustrates an example of ratios of 1.1 or more among ratios between the gradients shown in FIG. 9B according to one or more embodiments.

FIG. 9D illustrates an example of ratios of 0.9 or less among ratios between the gradients shown in FIG. 9B according to one or more embodiments.

FIG. 10A illustrates an example of absolute values of a gradient that is determined for each of preset SOH sections, and shows a degree of a change of a reduction rate of a capacity for a cathode active material for the corresponding SOH section, according to one or more embodiments.

FIG. 10B illustrates an example of ratios of a gradient a_{N} for a current SOH section to a gradient a_{N-1} for a previous SOH section based on gradients shown in FIG. 10A according to one or more embodiments.

FIG. 10C illustrates an example of ratios of 1.1 or more among ratios between the gradients shown in FIG. 10B according to one or more embodiments.

FIG. 10D illustrates an example of ratios of 0.9 or less among ratios between the gradients shown in FIG. 10B according to one or more embodiments.

FIG. 11A illustrates an example of absolute values of a gradient that is determined for each of preset SOH sections, and shows a degree of a change of an electrode balance shift for the corresponding SOH section, according to one or more embodiments.

FIG. 11B illustrates an example of ratios of a gradient a_{N} for a current SOH section to a gradient a_{N-1} for a previous SOH section based on gradients shown in FIG. 11A according to one or more embodiments.

FIG. 11C illustrates an example of ratios of 1.1 or more among ratios between the gradients shown in FIG. 11B according to one or more embodiments.

FIG. 11D illustrates an example of ratios of 0.9 or less among ratios between the gradients shown in FIG. 11B according to one or more embodiments.

FIG. 12 illustrates an example method of determining an RUL of a battery based on a battery prediction model according to one or more embodiments.

FIG. 13A illustrates an example of a difference between an actual life of a battery and an RUL of the battery estimated using extrapolation according to one or more embodiments.

FIG. 13B illustrates an example of a difference between an actual life of a battery and an RUL of the battery estimated using an electrochemical battery model to which degradation parameters are applied according to one or more embodiments.

FIG. 14 illustrates an example method of notifying that a life of a battery has ended when a second SOH of the battery corresponds to a limit SOH according to one or more embodiments.

FIG. 15 illustrates an example vehicle according to one or more embodiments.

FIG. 16 illustrates an example mobile terminal according to one or more embodiments.

FIG. 17 illustrates an example electronic device according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

When a battery is charged without consideration of the degradation amount, it may be impossible to avoid the degradation conditions during, in an example, fast charging, which may lead to rapid degradation and result in a reduction in the battery life. Accordingly, in order to use the battery safely and efficiently, a technology for estimating a remaining useful life (RUL) of the battery at a current time is desired.

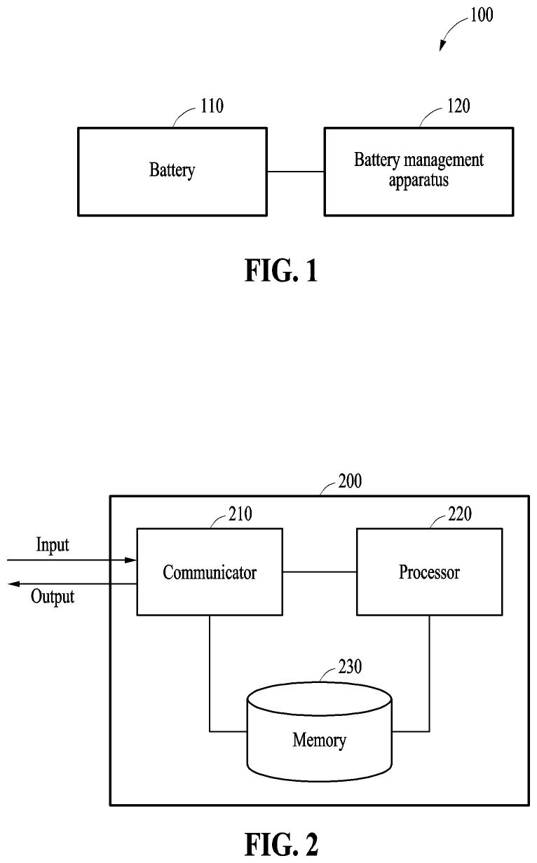

FIG. 1 illustrates an example battery system according to one or more embodiments.

Referring to FIG. 1, in a non-limiting example, battery system 100 may include a battery 110. The battery 100 may be one or more battery cells, battery modules, or battery packs. The battery 110 may include a capacitor, a secondary battery, or a lithium-ion battery for storing power as a result of charging. A device employing the battery 110 may receive power from the battery 110.

Repeated use of the battery 110 expedites degradation, and the degradation amount of the battery 110 may vary depending on the usage history of the battery 110.

In an example, a battery management apparatus 120 may determine a current state of the battery 110 using a battery model, and then determine the RUL of the battery based on the current state. In an example, the battery management apparatus 120 may estimate an internal state of the battery based on the battery model, and determine the RUL of the battery based on the estimated internal state of the battery. Here, the battery model may be an electrochemical model to which degradation parameters of the battery 110 are applied to estimate state information of the battery 110. The battery model may model internal physical phenomena such as potential and ion concentration distribution of the battery 110. In addition, the internal state of the battery 110 may include any one or any combination of a cathode lithium ion concentration distribution, an anode lithium ion concentration distribution, an electrolyte lithium ion concentration distribution, a cathode potential, and an anode potential of the battery 110. In an example, the degradation parameters may include any one or any combination of an electrode balance shift, a capacity for a cathode active material, and an anode surface resistance of the battery 110. However, examples are not limited thereto.

The battery 110 may include two electrodes (i.e., a cathode and anode) for intercalation/deintercalation of lithium ions, an electrolyte that is a medium through which lithium ions may move, a separator that physically separates the cathode and the anode to prevent direct flow of electrons but to allow ions to pass therethrough, and a collector that collects electrons generated by an electrochemical reaction or supplies electrons required for an electrochemical reaction. The cathode may include a cathode active material, and the anode may include an anode active material. In an example, lithium cobalt oxide (LiCoO₂) may be used as the cathode active material, and graphite (C₆) may be used as the anode active material. Lithium ions move from the cathode to the anode while the battery 110 is charged, and lithium ions move from the anode to the cathode while the battery 110 is discharged. Thus, the concentration of lithium ions in the cathode active material and the concentration of lithium ions in the anode active material change in response to charging and discharging.

The electrochemical model may be employed in various manners to express the internal state of the battery 110. In an example, a single particle model (SPM) and various application models may be employed for the electrochemical model, and parameters defining the electrochemical model may be variously modified depending on a design intention. The internal state conditions may be derived from the electrochemical model of the battery 110, or may be derived experimentally or empirically. Here, the technique of defining the internal state conditions is not limited.

Hereinafter, a method of determining the RUL of the battery 110 using a battery model based on an electrochemical model will be described in detail with reference to FIGS. 2 to 17.

FIG. 2 illustrates an example electronic device according to one or more embodiments.

Referring to FIG. 2, in a non-limiting example, an electronic device 200 may include a communicator 210, a processor 220, and a memory 230. In an example, the electronic device 200 may correspond to the battery management apparatus 120 described above with reference to FIG. 1.

In an example, the electronic device 200 may be included in a mobile communication terminal. In an example, the electronic device 200 may be included in a vehicle.

In an example, the communicator 210 (e.g., an I/O interface) may be connected to the processor 220 and the memory 230 and transmit and receive data to and from the processor 220 and the memory 230. The communicator 210 may be connected to another external device and transmit and receive data to and from the external device. The communicator 210 may include a network module for connecting to a network and/or a server, and a module for forming a data transfer channel with a mobile storage medium. Hereinafter, transmitting and receiving “A” may refer to transmitting and receiving “information or data indicating A”.

The communicator 210 may be implemented as circuitry in the electronic device 200. For example, the communicator 210 may include an internal bus and an external bus. In another example, the communicator 210 may be an element that connects the electronic device 200 to the external device. The communicator 210 may be an interface. The communicator 210 may receive data from the external device and transmit the data to the processor 220 and the memory 230.

The processor 220 may process the data received by the communicator 210 and data stored in the memory 230. The processor 220 may be configured to execute programs or applications to configure the processor 220 to control the electronic device to perform one or more or all operations and/or methods involving the calculation and/or determination of a battery's RUL, and may include any one or a combination of two or more of, for example, a central processing unit (CPU), a graphic processing unit (GPU), a neural processing unit (NPU) and tensor processing units (TPUs), a microprocessor, a processor core, a multi-core processor, a multiprocessor, an application-specific integrated circuit (ASIC), and a field-programmable gate array (FPGA). The processor 220 may include one or more processors.

The memory 230 may store the data received by the communicator 210 and the data processed by the processor 220. The memory 230 may include computer-readable instructions. The processor 220 may be configured to execute computer-readable instructions, such as those stored in the memory 230, and through execution of the computer-readable instructions, the processor 220 is configured to perform one or more, or any combination, of the operations and/or methods described herein. The memory 230 may be a volatile or nonvolatile memory.

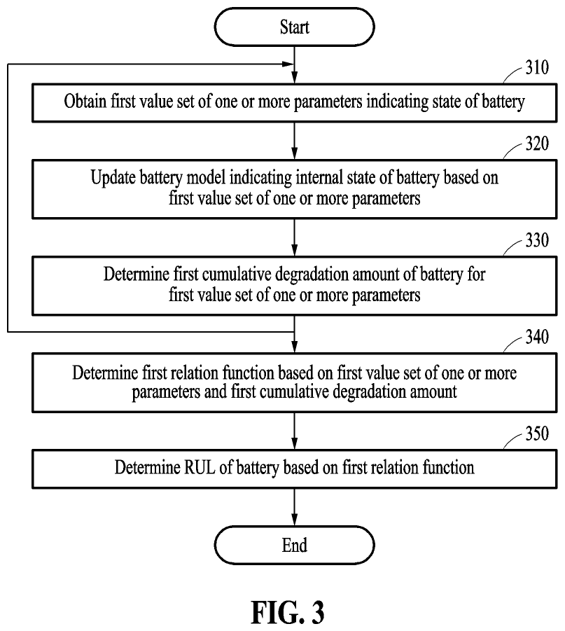

The communicator 210, the processor 220, and the memory 230 will be described in greater detail below with reference to FIGS. 3 to 17.

FIG. 3 illustrates an example method of determining an RUL of a battery according to one or more embodiments.

Operations 310 through 350 may be performed by the electronic device (e.g., the electronic device 200 of FIG. 2) described above with reference to FIG. 2.

Referring to FIG. 3, in a non-limiting example, in operation 310, an electronic device may obtain a first value set of one or more parameters indicating a state of a battery (e.g., the battery 110 of FIG. 1). The parameters indicating the state of the battery may be referred to as degradation parameters, and the degradation parameters may include an electrode balance shift, a capacity for a cathode active material, and an anode surface resistance of the battery. The first value set of the one or more parameters may be a set or group of values of one or more parameters obtained at the same time point.

In operation 320, the electronic device may update a battery model that indicates an internal state of the battery based on the obtained first value set of the one or more parameters. In an example, the battery model may be an electrochemical model that estimates an internal state of a battery based on various parameters. The battery model may estimate internal state information of the battery by modeling an internal physical phenomenon, such as a potential or an ion concentration distribution of the battery.

The electrochemical model may be employed in various manners to express the internal state of the battery. In an example, an SPM and various application models may be employed for the electrochemical model, and parameters that define the electrochemical model may be variously modified depending on a design intention.

In an example, the internal state of the battery that may be estimated by the battery model may include any one or any combination of a cathode lithium ion concentration distribution, an anode lithium ion concentration distribution, an electrolyte lithium ion concentration distribution, a cathode potential, and an anode potential of the battery.

As the one or more parameters of the battery model are adjusted based on the degradation parameters, the internal state of the battery that is estimated by the battery model may be changed.

In operation 330, the electronic device may determine a first cumulative degradation amount rate of the battery for the first value set of the one or more parameters. In an example, the electronic device may determine the first cumulative degradation amount of the battery corresponding to the first value set of the one or more parameters using a battery model.

In an example, the cumulative degradation amount of the battery in a fresh state may be 0, and the cumulative degradation amount of the battery may increase as the number of charge and discharge cycles of the battery increases. The first cumulative degradation amount of the battery may be a cumulative degradation amount in a state in which a degraded state of the battery is indicated by the first value set of the one or more parameters. In an example, the cumulative degradation amount may include an amount of anode side reactions that occur during charging and discharging of the battery.

In an example, the electronic device may calculate a side reaction current based on charging current data used to charge a battery. In an example, the side reaction current may be calculated based on a Butler-Volmer equation.

The Butler-Volmer equation is a calculation formula that obtains an amount of lithium ions consumed by an anode side reaction (that is, an amount of anode side reaction) and may be expressed by Equation 1 below.

$${j}_{side}^{Li} = {a}_{s} {i}_{0 , side} [ exp ( \frac{{α}_{a , side} {n}_{side} F}{RT} {η}_{side} ) - exp ( - \frac{{α}_{c , side} {n}_{side} F}{RT} {η}_{side} ) ] \qquad Equation 1$$

In Equation 1, j_{side}^{Li} denotes an electrode current density related to lithium ion consumption by an anode side reaction, and an amount of lithium ions consumed by the anode side reaction may be obtained by integrating j_{side}^{Li} with respect to time. In Equation 1, as denotes an active surface area of an anode, and i_{0,side} denotes an exchange current density for the anode side reaction. In addition, α_{a,side} denotes an anodic charge transfer coefficient, α_{c,side} denotes a cathodic charge transfer coefficient, and for example, the anodic charge transfer coefficient and the cathodic charge transfer coefficient may each have a value of 0.5. Next, n_{side} denotes a number of molecules involved in the anode side reaction, F denotes a Faraday constant, R denotes an ideal gas constant, and T denotes a temperature. Finally, η_{side} denotes an anode overpotential for a side reaction and may be expressed by Equation 2 below.

$${η}_{side} = {ϕ}_{s} - {ϕ}_{e} - {U}_{eq , side} - \frac{{R}_{SEI , total}}{{a}_{s , side}} {j}_{total}^{Li} \qquad Equation 2$$

In Equation 2, ϕₛ denotes a potential of a solid, and ϕₑ denotes a potential of an electrolyte. In Equation 2, U_{eq,side} denotes an equilibrium potential for the side reaction and may be set to 0.4 volts (V), for example. In Equation 2, R_{SE,total} denotes a resistance by a solid electrolyte interphase (SEI) layer formed on an anode surface, a_{s,side} denotes an active surface area of the anode, and jₜₒₜₐₗ^{Li} denotes an electrode current density related to all lithium ions.

The exchange current density i_{0,side} described above may be expressed by Equation 3 below.

$${i}_{0 , side} = {k}_{side} \sqrt{{c}_{s , surf} {c}_{EC , Rs}} \qquad Equation 3$$

In Equation 3, k_{side} denotes a kinetic rate constant for the side reaction, c_{s,surf} denotes a lithium ion concentration on an electrode (for example, anode) surface, and C_{EC,Rs} denotes an electrolyte concentration on the electrode surface.

Based on the remaining terms, excluding C_{s,surf} in the right term of Equation 3, the degradation rate coefficient k_{eff} may be expressed by Equation 4. The degradation rate coefficient k_{eff} may denote an degradation property of a battery.

$${k}_{eff} = {k}_{side} \sqrt{{c}_{EC , Rs}} \qquad Equation 4$$

The electronic device (e.g., electronic device 200) may determine the cumulative degradation amount or the degradation rate of the battery based on the determined degradation rate coefficient. In an example, the degradation rate of the battery may be predicted from the determined degradation rate coefficient by modeling a tendency of a change in the degradation rate coefficient according to the degradation of the battery. In general, it is known that an electrode balance shift, which has a corresponding relationship with the degradation rate coefficient, has a high correlation with a state of health (SOH). The degradation rate, or the cumulative degradation amount of the battery, may be determined based on the determined degradation rate coefficient by modeling a tendency of a change of the degradation rate coefficient based on the above characteristic.

In an example, the SOH is a parameter quantitatively indicating a change in the life characteristic of a battery caused by degradation, and may indicate a degree of degradation in the life or capacity of the battery. Various schemes may be employed to estimate or measure an SOH. In an example, an SOH of a battery in a fresh state may be determined as 1, and the SOH of the battery may decrease below 1 as the number of charge and discharge cycles of the battery increases.

The electronic device may determine the SOH of the battery using one or more parameters indicating the state of the battery or a battery model.

The electronic device may calculate an internal resistance of the battery, and determine the SOH of the battery based on the calculated internal resistance.

In operation 340, the electronic device (e.g., electronic device 200) may determine a first relation function based on the first value set of the one or more parameters and the first cumulative degradation amount.

In an example, the electronic device may determine the first relation function by adjusting a most recently determined relation function (e.g., a previous relation function) based on the first value set and the first cumulative degradation amount. The electronic device may determine the first relation function by updating a previous relation function determined based on a previous difference set determined before a first difference set and a previous cumulative degradation amount determined before the first cumulative degradation amount based on the first difference set and the first cumulative degradation amount. In an example, the electronic device may determine the first relation function by adjusting at least one of one or more constant terms expressing the previous relation function.

The first relation function may be determined based on a (t−2)-th correlation between a (t−2)-th value set and a (t−2)-th cumulative degradation amount, a (t−1)-th correlation between a (t−1)-th value set and a (t−1)-th cumulative degradation amount, and a t-th correlation between a t-th value set (e.g., the first value set) and a t-th cumulative degradation amount (e.g., the first cumulative degradation amount).

The values of the one or more parameters may greatly change as the battery is degraded, and thus, the first relation function may be determined based on the first value set of the one or more parameters and the first cumulative degradation amount.

In an example, the first relation function may be expressed as an equation or a model based on a neural network and is not limited to the described example.

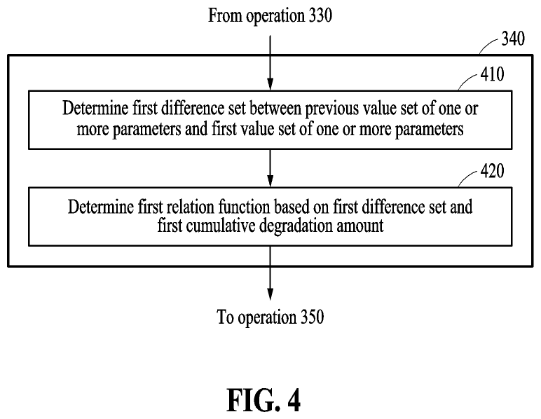

The method of determining the first relation function will be described in detail below with reference to FIGS. 4 to 11B.

In operation 350, the electronic device may determine an RUL of the battery based on the first relation function. In an example, the RUL of a battery may be a life remaining until an SOH of the battery reaches a limit SOH preset for the battery or a life remaining until a value of a parameter indicating a degraded state of the battery reaches a limit value preset for the battery. In an example, the RUL of a battery may be calculated based on the number of charge and discharge cycles.

The electronic device may determine the RUL of the battery based on a learned charging and discharging pattern of the battery. The electronic device may determine the RUL of the battery based on one or more received charging and discharging conditions.

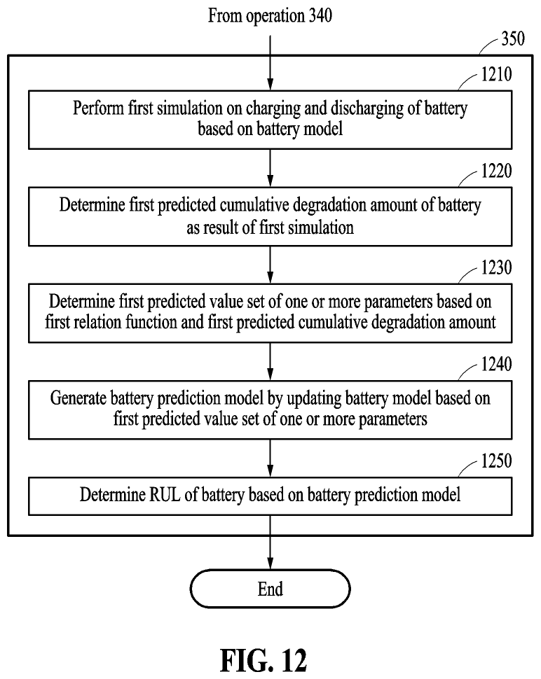

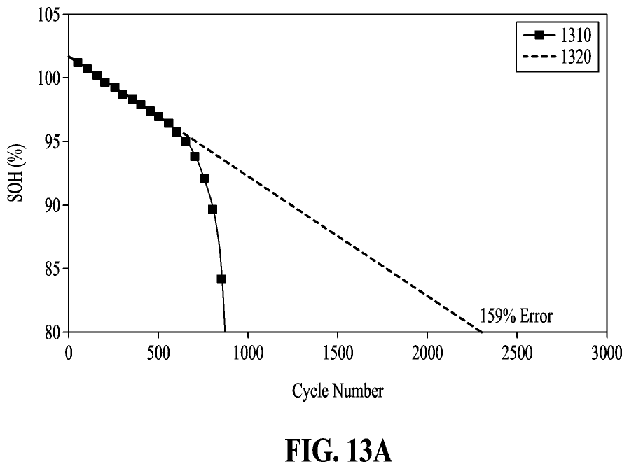

The electronic device may perform a first simulation on charging and discharging of the battery based on a battery model and a first relation function, and update the battery model based on a predicted cumulative degradation amount derived as a result of the first simulation and a predicted value set of one or more parameters. The electronic device may perform a second simulation on charging and discharging of the battery based on the updated battery model and the first relation function. By repeating the simulations on charging and discharging of the battery, the electronic device may determine the number of charge and discharge cycles of the battery performed until the SOH of the battery reaches the limit SOH preset for the battery or a value of a parameter indicating the degraded state of the battery reaches a limit value preset for the battery. For example, the determined number of charge and discharge cycles of the battery may be determined as the RUL of the battery. Hereinafter, the method of determining the RUL of the battery based on the first relation function will be described in detail with reference to FIG. 12.

In an example, the electronic device may receive a request for calculating the RUL of the battery from a user. In an example, the electronic device may receive a request for calculating the RUL of the battery from the user through a user interface. The electronic device may determine the RUL of the battery based on the first relation function in response to the request for calculating the RUL.

FIG. 4 illustrates an example method of determining a first relation function based on a first value set of one or more parameters and a first cumulative degradation amount according to one or more embodiments.

Referring to FIG. 4, in a non-limiting example, operation 340 described above with reference to FIG. 3 may include operations 410 and 420 described below. Operations 410 and 420 may be performed by an electronic device (e.g., the electronic device 200 described above with reference to FIG. 2).

In operation 410, the electronic device may determine a first difference set between the first value set and a previous value set of one or more parameters determined before the first value set of the one or more parameters indicating a state of a battery (e.g., the battery 110 of FIG. 1) is determined. The previous value set may be, for example, a set of values of the one or more parameters which are determined most recently or immediately before the first value set is determined.

In operation 420, the electronic device may determine the first relation function based on the first difference set of the one or more parameters and the first cumulative degradation amount. In an example, the first relation function may be determined to indicate a correlation between the first difference set and an increase of the cumulative degradation amount. In an example, the first relation function may be determined to indicate a correlation between a plurality of difference sets and increases in the cumulative degradation amount. The increase of the cumulative degradation amount may be a difference between a previous cumulative degradation amount and a next cumulative degradation amount. In an example, the first relation function may be determined based on the (t−2)-th correlation between a (t−2)-th difference set and an increase of the (t−2)-th cumulative degradation amount, the (t−1)-th correlation between a (t−1)-th difference set and an increase of the (t−1)-th cumulative degradation amount, and the t-th correlation between a t-th difference set (e.g., the first difference set) and an increase of the t-th cumulative degradation amount (e.g., the increase of the first cumulative degradation amount).

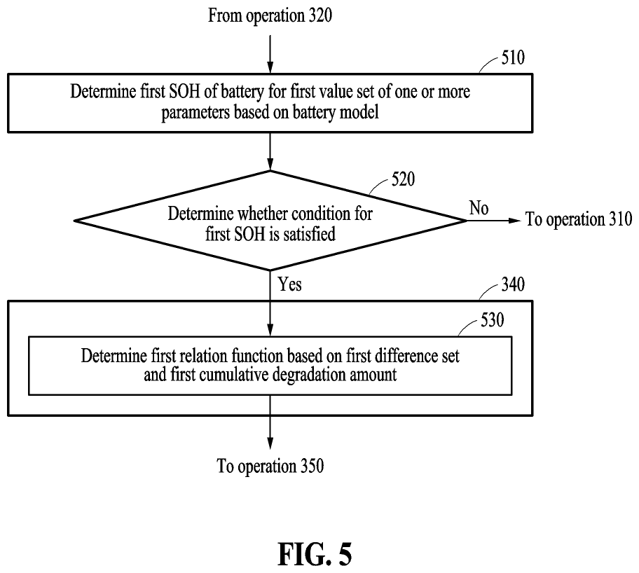

FIG. 5 illustrates an example method of determining a first relation function when a condition for a first SOH of a battery is satisfied according to one or more embodiments.

According to an example, operations 510 and 520 may be further performed after operation 320 (or operation 330) described above with reference to FIG. 3 is performed. Operations 510 and 520 may be performed by an electronic device (e.g., the electronic device 200 of FIG. 2). Operations 510 and 520 may be performed in parallel to or independently of operation 330 of FIG. 3.

Referring to FIG. 5, in a non-limiting example, in operation 510, the electronic device may determine a first SOH of the battery for the first value set of the one or more parameters based on the battery model. The determined first SOH may indicate a current degradation degree of the battery.

In operation 520, the electronic device may determine whether a condition for the first SOH is satisfied based on the first SOH. In an example, when the first SOH is less than or equal to a target SOH where the target SOH is preset to start determining a relation function between the values of the one or more parameters and the cumulative degradation amount, it may be determined that the condition for the first SOH is satisfied. The target SOH may be, for example, 0.95, but examples are not limited thereto.

The determination of the relation function starts when the first SOH is less than or equal to the target SOH. The determination starts in order to obtain sufficient data regarding a change of values of the one or more parameters and data for a cumulative degradation amount corresponding to the change of the values of the one or more parameters according to the degradation of the battery. That is, the more data obtained, the more accurately the relation function determined based on the data may reflect the actual phenomenon.

When the first SOH exceeds the target SOH, operations 310 to 330 of FIG. 3 may be performed repeatedly.

Operation 340 is described above in greater detail with reference to FIG. 3 and operation 340 may include operation 530. In an example, operation 530 may be performed when the condition for the first SOH is satisfied.

In operation 530, the electronic device may determine the first relation function based on the first difference set of the one or more parameters and the first cumulative degradation amount. In an example, the description of operation 530 may be replaced with the description of operation 420 provided above with reference to FIG. 4.

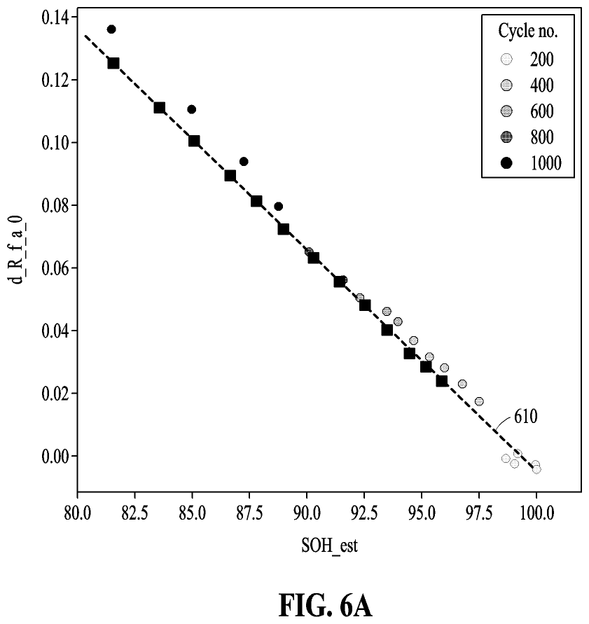

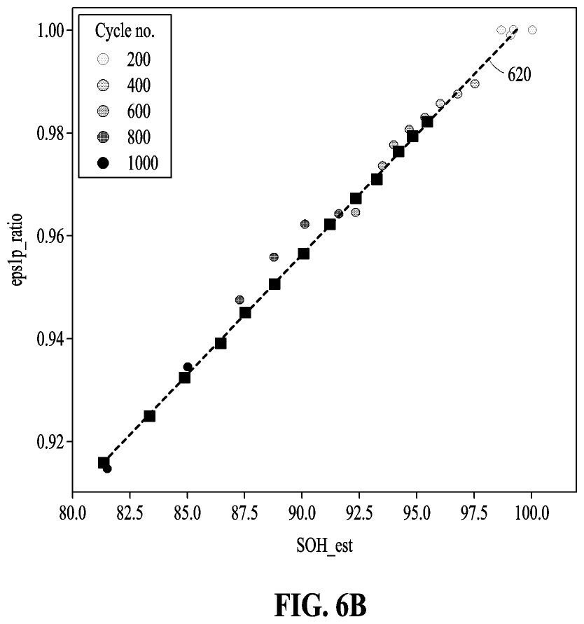

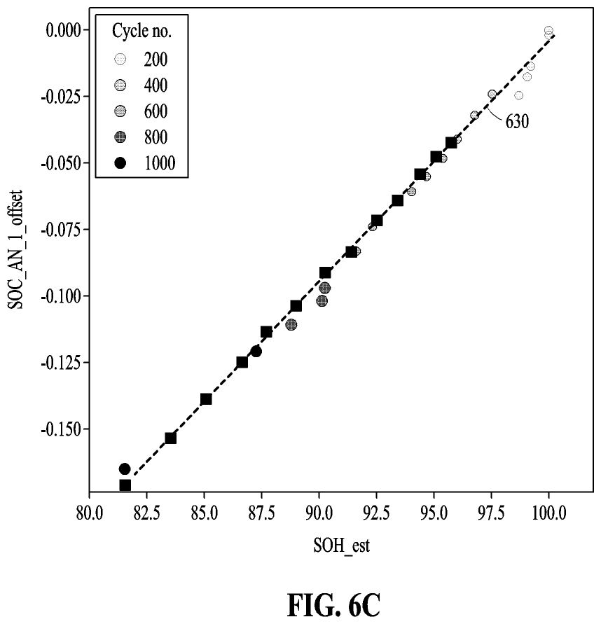

FIG. 6A illustrates a correlation between an SOH of a battery and an anode surface resistance according to one or more embodiments.

A value of the anode surface resistance, which is a degradation parameter, increases as the battery is degraded. There is a high correlation between the cumulative degradation amount and the SOH of the battery. Accordingly, a correlation between the SOH and the anode surface resistance may be similar to a correlation between the cumulative degradation amount and the anode surface resistance.

Referring to FIG. 6A, in a non-limiting example, the actually measured values of the anode surface resistance are shown as round points on a graph and their respective shading corresponds to the number of charge and discharge cycles. For example, the values of the anode surface resistance for the number of cycles of 200, the number of cycles of 400, the number of cycles of 600, the number of cycles of 800, and the number of cycles of 1000 are each shown with corresponding SOH. The actually measured values tend to increase in inverse proportion to the SOH as the SOH decreases.

An electronic device (e.g., the electronic device 200 of FIG. 2) may obtain values of the anode surface resistance of the battery while the SOH decreases from 1 to 0.96. The electronic device may update the battery model using the value of the anode surface resistance, and calculate a cumulative degradation amount of the battery based on the battery model. The cumulative degradation amount may have a high correlation with the SOH. When the SOH of the battery corresponds to the target SOH (e.g., 0.96 in the illustrated example), the first relation function may be determined based on the values of the anode surface resistance and the cumulative degradation amount. In an example, the electronic device may determine a trend line 610 based on the values of the anode surface resistance obtained while the SOH decreases from 1 to 0.96, and predict values of the anode surface resistance according to the change of the SOH based on the trend line 610. The predicted values of the anode surface resistance are shown as square points on a graph.

FIG. 6B illustrates a correlation between an SOH of a battery and a reduction rate of a capacity of a cathode active material according to one or more embodiments.

A value of the reduction rate of the capacity for the cathode active material, which is a degradation parameter, decreases as the battery is degraded. As described above, there is a high correlation between the cumulative degradation amount and the SOH of the battery. Accordingly, the correlation between the SOH and the reduction rate of the capacity for the cathode active material may be similar to a correlation between the cumulative degradation amount and the reduction rate of the capacity for the cathode active material.

Referring to FIG. 6B, in a non-limiting example, the actually measured values of the reduction rate of the capacity for the cathode active material are shown as round points on a graph and include shading that corresponds to the number of charge and discharge cycles. For example, the values of the reduction rate of the capacity for the cathode active material for the number of cycles of 200, the number of cycles of 400, the number of cycles of 600, the number of cycles of 800, and the number of cycles of 1000 are each shown with corresponding SOH. The actually measured values tend to decrease in proportion to the SOH as the SOH decreases.

An electronic device (e.g., the electronic device 200 of FIG. 2) may obtain values of the reduction rate of the capacity for the cathode active material of the battery while the SOH decreases from 1 to 0.96. The electronic device may update the battery model using the value of the reduction rate of the capacity for the cathode active material, and calculate a cumulative degradation amount of the battery based on the battery model. The cumulative degradation amount may have a high correlation with the SOH. When the SOH of the battery corresponds to the target SOH (e.g., 0.96 in the illustrated example), the first relation function may be determined based on the values of the reduction rate of the capacity for the cathode active material and the cumulative degradation amount. In an example, the electronic device may determine a trend line 620 based on the values of the reduction rate of the capacity for the cathode active material obtained while the SOH decreases from 1 to 0.96, and predict values of the reduction rate of the capacity for the cathode active material according to the change of the SOH based on the trend line 620. The predicted values of the reduction rate of the capacity for the cathode active material are shown as square points on a graph.

FIG. 6C illustrates a correlation between an SOH of a battery and an electrode balance shift according to one or more embodiments.

A value of an electrode balance shift, which is a degradation parameter, decreases as the battery is degraded. As described above, there is a high correlation between the cumulative degradation amount and the SOH of the battery. Accordingly, a correlation between the SOH and the electrode balance shift may be similar to a correlation between the cumulative degradation amount and the electrode balance shift.

Referring to FIG. 6C, in a non-limiting example, the actually measured values of the electrode balance shift are shown as round points on a graph, and being shaded to correspond to the number of charge and discharge cycles. For example, the values of the electrode balance shift for the number of cycles of 200, the number of cycles of 400, the number of cycles of 600, the number of cycles of 800, and the number of cycles of 1000 are each shown with corresponding SOH. The actually measured values tend to decrease in proportion to the SOH as the SOH decreases.

An electronic device (e.g., the electronic device 200 of FIG. 2) may obtain values of the electrode balance shift of the battery while the SOH decreases from 1 to 0.96. The electronic device may update the battery model using the value of the electrode balance shift, and calculate a cumulative degradation amount of the battery based on the battery model. The cumulative degradation amount may have a high correlation with the SOH. When the SOH of the battery corresponds to the target SOH (e.g., 0.96 in the illustrated example), the first relation function may be determined based on the values of the electrode balance shift and the cumulative degradation amount. In an example, the electronic device may determine a trend line 630 based on the values of the electrode balance shift obtained while the SOH decreases from 1 to 0.96, and predict values of the electrode balance shift according to the change of the SOH based on the trend line 630. The predicted values of the electrode balance shift are shown as square points on a graph.

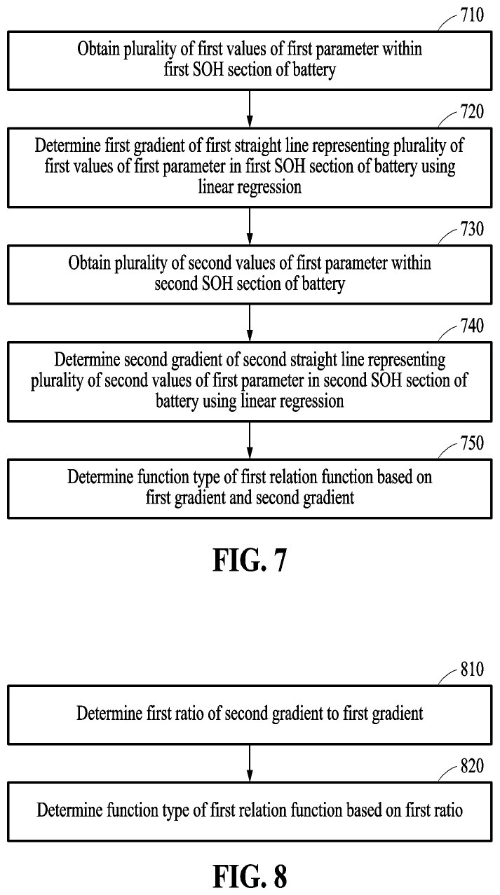

FIG. 7 illustrates an example method of determining a function type of a first relation function according to one or more embodiments.

In an example, operations 710 to 750 may be performed before operation 340 described above with reference to FIG. 3 is performed. Operations 710 to 750 may be performed by an electronic device (e.g., the electronic device 200 of FIG. 2).

Referring to FIG. 7, in a non-limiting example, in operation 710, the electronic device may obtain a plurality of first values of a first parameter within a first SOH section of a battery. In an example, the first parameter may be an electrode balance shift, a capacity for a cathode active material, or an anode surface resistance of a battery. For example, the first SOH section may be a section from SOH 1.0 to SOH 0.97. For example, a range of the SOH section is set to ΔSOH 0.03, however, the range of the SOH section may vary depending on the setting. The plurality of first values of the first parameter may be values of the first parameter obtained in the section of SOH 1.0 to SOH 0.97.

In operation 720, the electronic device may determine a first gradient of a first straight line representing the plurality of first values of the first parameter in the first SOH section of the battery using linear regression. The first gradient in the section of SOH 1.0 to SOH 0.97 may be associated with SOH 0.97.

In operation 730, the electronic device may obtain a plurality of second values of the first parameter within a second SOH section of the battery. For example, the second SOH section may be a section from SOH 0.99 to SOH 0.96. The second SOH section may be a next section of the first SOH section. For example, when the SOH is changed from 0.97 to 0.96, the second SOH section may be newly defined or generated.

The plurality of second values of the first parameter may be values of the first parameter obtained in the section of SOH 0.99 to SOH 0.96.

In operation 740, the electronic device may determine a second gradient of a second straight line representing the plurality of second values of the first parameter in the second SOH section of the battery using linear regression. The second gradient in the section of SOH 0.99 to SOH 0.96 may be associated with SOH 0.96.

In operation 750, the electronic device may determine a function type of the first relation function based on the first gradient of the first straight line and the second gradient of the second straight line. In an example, the function type of the first relation function may be a function type in which a gradient of the first relation function increases as the SOH decreases. In an example, the function type of the first relation function may be a function type in which the gradient of the first relation function decreases as the SOH decreases. In an example, the function type of the first relation function may be a function type in which the gradient of the first relation function does not change even when the SOH decreases.

A method of determining the function type of the first relation function based on the first gradient of the first straight line and the second gradient of the second straight line will be described in detail below with reference to FIG. 8.

FIG. 8 illustrates an example method of determining a function type of a first relation function based on a first gradient and a second gradient according to one or more embodiments.

In an example, operation 750 described above with reference to FIG. 7 may include operations 810 and 820 to be described hereinafter. Operations 810 and 820 may be performed by an electronic device (e.g., the electronic device 200 of FIG. 2).

Referring to FIG. 8, in a non-limiting example, in operation 810, the electronic device may determine a first gradient ratio of the second gradient to the first gradient of the first straight line. In an example, when the first gradient is expressed as a_{N-1} and the second gradient is expressed as a_{N}, the first gradient ratio may be expressed as a_{N}/a_{N-1}. When the first SOH section is a section of SOH 1 to 0.97 and the second SOH section is a section of SOH 0.99 to 0.96, the first gradient ratio may be associated with SOH 0.96.

A second gradient ratio and a third gradient ratio may be determined similarly to the method of determining the first gradient ratio. In an example, in the electronic device, when the second SOH section is a section of SOH 0.99 to 0.96 and a third SOH section is a section of SOH 0.98 to 0.95, the second gradient ratio to be determined may be associated with SOH 0.96. The third gradient ratio may be associated with SOH 0.95.

In operation 820, the electronic device may determine a function type of the first relation function based on the first gradient ratio. In an example, the electronic device may determine the function type of the first relation function based on the tendency of the changes of the first gradient ratio, the second gradient ratio, and the third gradient ratio determined according to the change of the SOH.

When the first gradient ratio, the second gradient ratio, and the third gradient ratio tend to gradually increase, the function type of the first relation function may be a function type in which the gradient of the first relation function increases as the SOH decreases. In an example, when a proportion of gradient ratios having a value of the gradient ratio greater than a preset first threshold value (e.g., 1.1) is high, the function type of the first relation function may be determined to be a function type in which the gradient increases.

When the first gradient ratio, the second gradient ratio, and the third gradient ratio tend to gradually decrease, the function type of the first relation function may be a function type in which the gradient of the first relation function decreases as the SOH decreases. In an example, when a proportion of gradient ratios having a value of the gradient ratio smaller than a preset second threshold value (e.g., 0.9) is high, the function type of the first relation function may be determined to be a function type in which the gradient decreases.

When the first gradient ratio, the second gradient ratio, and the third gradient ratio tend to be maintained within a certain range, the function type of the first relation function may be a function type in which the gradient of the first relation function does not change even when the SOH decreases. In an example, when a proportion of gradient ratios having a value of the gradient ratio between the preset first threshold value (e.g., 1.1) and the second threshold value (e.g., 0.9) is high, the function type of the first relation function may be determined to be a function type in which the gradient does not change.

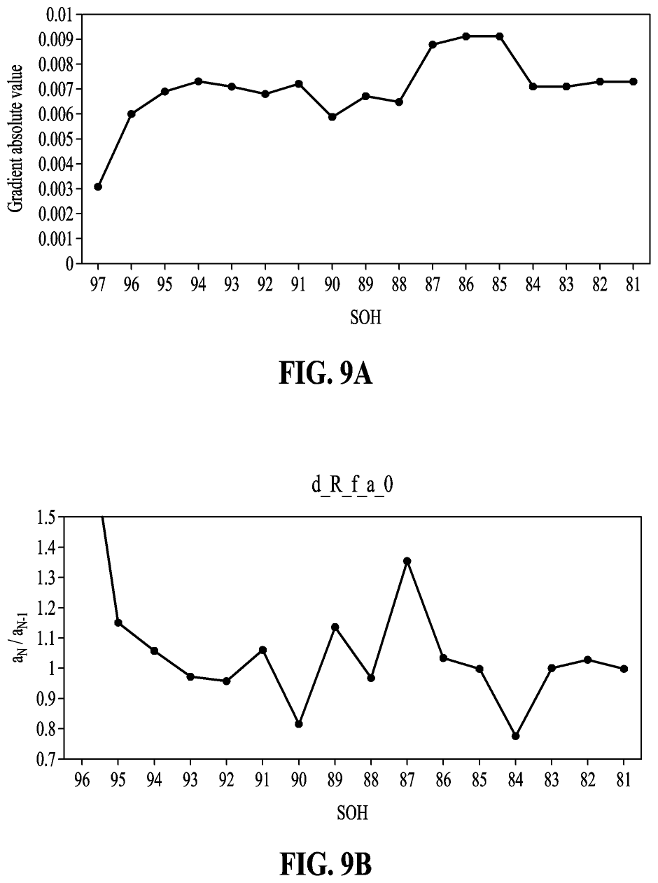

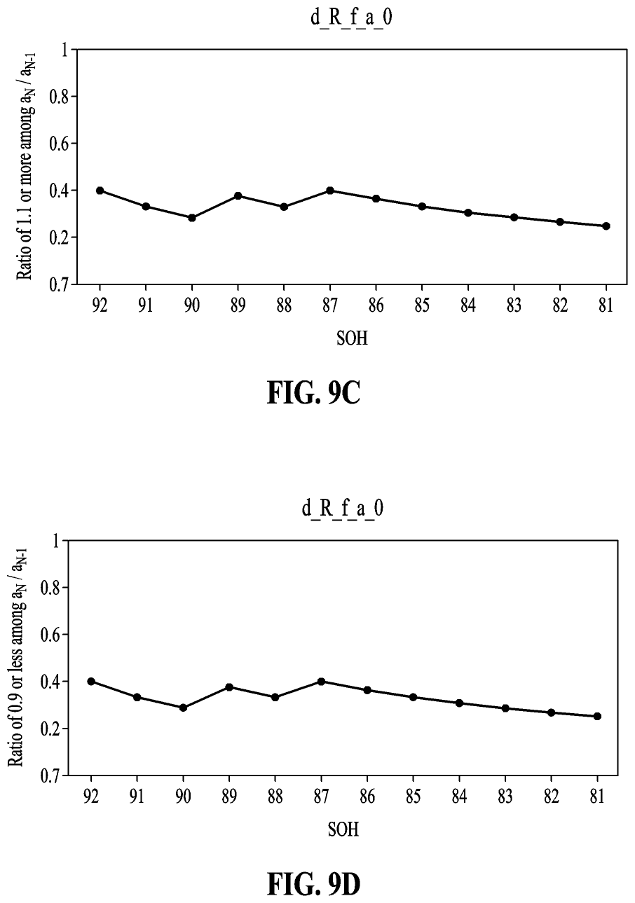

FIG. 9A illustrates an example of absolute values of a gradient that is determined for each of preset SOH sections, and shows a degree of a change of an anode surface resistance value for the corresponding SOH section.

An absolute value of a gradient for a change of an anode surface resistance value associated with each of the SOHs is shown.

FIG. 9B illustrates an example of ratios of a gradient a_{N} for a current SOH section to a gradient a_{N-1} for a previous SOH section based on gradients shown in FIG. 9A according to one or more embodiments.

Referring to FIG. 9B, in a non-limiting example, a gradient ratio for SOH 0.95 may be a ratio between an absolute value of a gradient associated with SOH 0.96 and an absolute value of a gradient associated with SOH 0.95. Because the absolute value of the gradient associated with SOH 0.96 is 0.006, and the absolute value of the gradient associated with SOH 0.95 is 0.007, the gradient ratio for SOH 0.95 may be determined to be 1.167.

FIG. 9C illustrates an example of ratios of 1.1 or more among gradient ratios shown in FIG. 9B according to one or more embodiments.

In an example, among the determined gradient ratios for the SOHs until the SOH of the battery reaches 0.92, a proportion of gradient ratios having a value greater than or equal to the first threshold value (e.g., 1.1) may be calculated as 0.4.

Referring to FIG. 9C, in a non-limiting example, when a current SOH of the battery is determined as the first SOH, an electronic device (e.g., the electronic device 200 of FIG. 2) may calculate a proportion of gradient ratios having a value greater than or equal to the first threshold value (e.g., 1.1) among the determined gradient ratios for the SOHs until the SOH of the battery reaches the first SOH, and determine the type of the first relation function as a function type in which the gradient increases, when the calculated ratio is greater than or equal to a preset value (e.g., 0.7).

FIG. 9D illustrates an example of ratios of 0.9 or less among ratios between the gradients shown in FIG. 9B according to one or more embodiments.

In an example, among the determined gradient ratios for the SOHs until the SOH of the battery reaches 0.92, a proportion of gradient ratios having a value less than or equal to the second threshold value (e.g., 0.9) may be calculated as 0.4.

Referring to FIG. 9D, in a non-limiting example, when a current SOH of the battery is determined as the first SOH, an electronic device (e.g., the electronic device 200 of FIG. 2) may calculate a proportion of gradient ratios having a value less than or equal to the second threshold value (e.g., 0.9) among the determined gradient ratios for the SOHs until the SOH of the battery reaches the first SOH, and determine the type of the first relation function as a function type in which the gradient decreases, when the calculated ratio is greater than or equal to a preset value (e.g., 0.7).

When the type of the first relation function is not determined as the type in which the gradient increases or the gradient decreases, the type of the first relation function may be determined as the function type in which the gradient does not change.

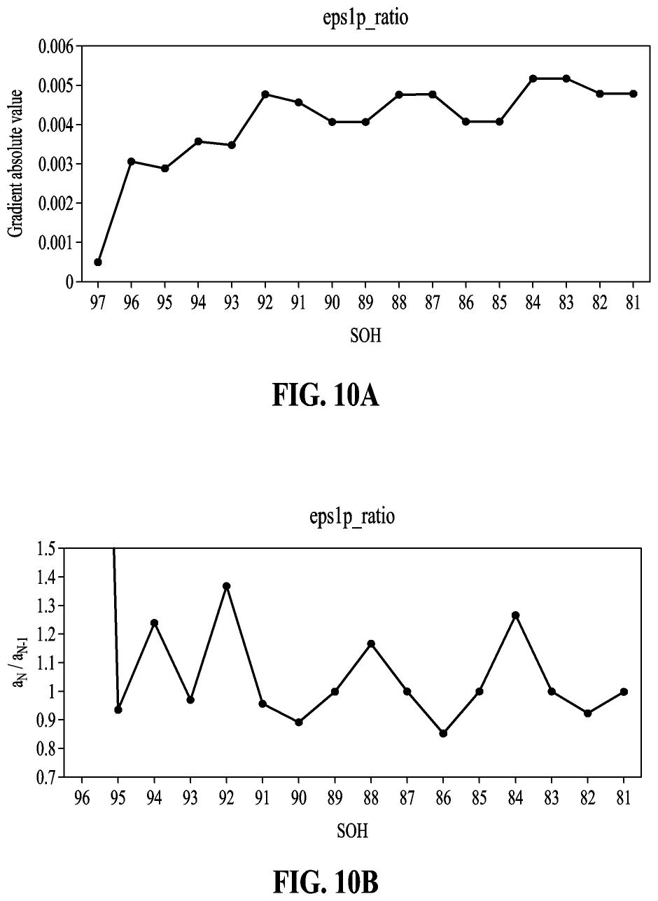

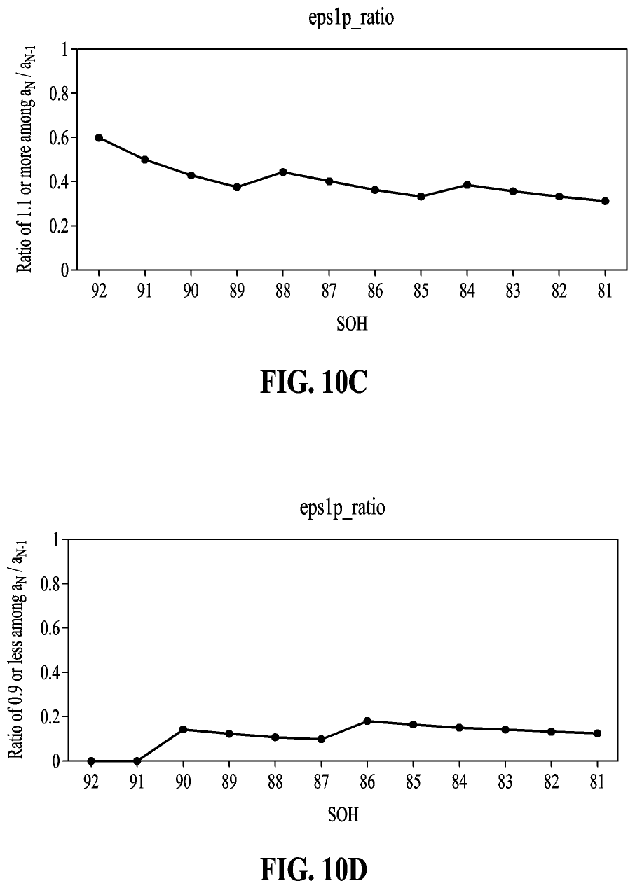

FIG. 10A illustrates an example of absolute values of a gradient that is determined for each of preset SOH sections according to one or more embodiments. Referring to FIG. 10A, in a non-limiting example, a degree of a change of a reduction rate of a capacity for a cathode active material for the corresponding SOH section is illustrated.

An absolute value of a gradient for a change of a reduction rate of a capacity for a cathode active material associated with each of the SOHs is shown.

FIG. 10B illustrates an example of ratios of a gradient a_{N} for a current SOH section to a gradient a_{N-1} for a previous SOH section based on gradients shown in FIG. 10A according to one or more embodiments.

Referring to FIG. 10B, in a non-limiting example, a gradient ratio for SOH 0.95 may be a ratio between an absolute value of a gradient associated with SOH 0.96 and an absolute value of a gradient associated with SOH 0.95. In FIG. 10A, since the absolute value of the gradient associated with SOH 0.96 is 0.0031, and the absolute value of the gradient associated with SOH 0.95 is 0.0029, the gradient ratio for SOH 0.95 may be determined to be 0.94.

FIG. 10C illustrates an example of ratios of 1.1 or more among ratios between the gradients shown in FIG. 10B according to one or more embodiments.

Referring to FIG. 10C, in a non-limiting example, among the determined gradient ratios for the SOHs until the SOH of the battery reaches 0.92, a proportion of gradient ratios having a value greater than or equal to the first threshold value (e.g., 1.1) may be calculated as 0.6.

When a current SOH of the battery is determined as the first SOH, an electronic device (e.g., the electronic device 200 of FIG. 2) may calculate a proportion of gradient ratios having a value greater than or equal to the first threshold value (e.g., 1.1) among the determined gradient ratios for the SOHs until the SOH of the battery reaches the first SOH, and determine the type of the first relation function as a function type in which the gradient increases, when the calculated ratio is greater than or equal to a preset value (e.g., 0.7).

FIG. 10D illustrates an example of ratios of 0.9 or less among ratios between the gradients shown in FIG. 10B according to one or more embodiments.

Referring to FIG. 10D, in a non-limiting example, among the determined gradient ratios for the SOHs until the SOH of the battery reaches 0.92, a proportion of gradient ratios having a value less than or equal to the second threshold value (e.g., 0.9) may be calculated as 0.

When a current SOH of the battery is determined as the first SOH, an electronic device (e.g., the electronic device 200 of FIG. 2) may calculate a proportion of gradient ratios having a value less than or equal to the second threshold value (e.g., 0.9) among the determined gradient ratios for the SOHs until the SOH of the battery reaches the first SOH, and determine the type of the first relation function as a function type in which the gradient decreases, when the calculated ratio is greater than or equal to a preset value (e.g., 0.7).

When the type of the first relation function is not determined as the type in which the gradient increases or the gradient decreases, the type of the first relation function may be determined as the function type in which the gradient does not change.

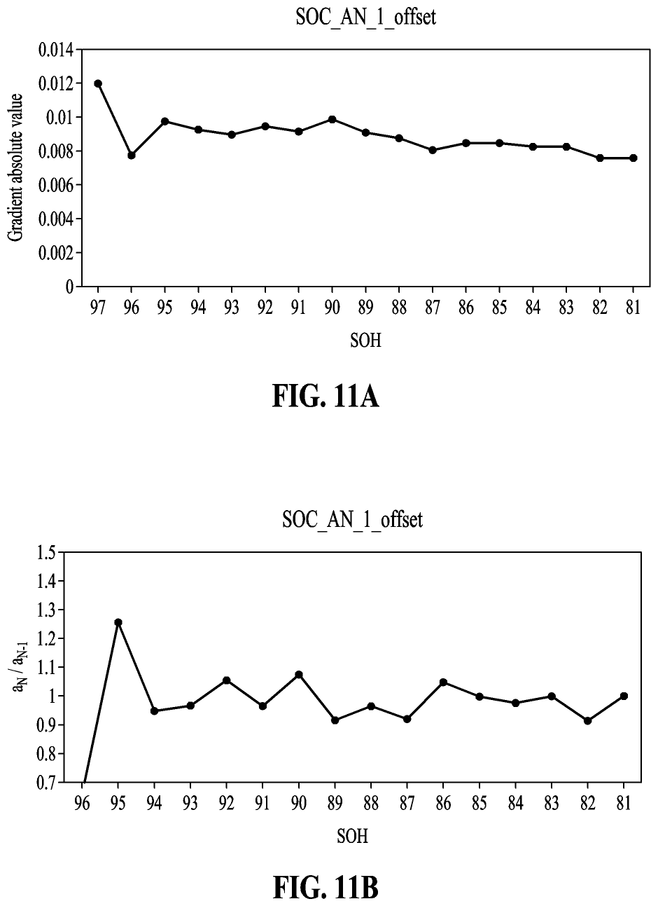

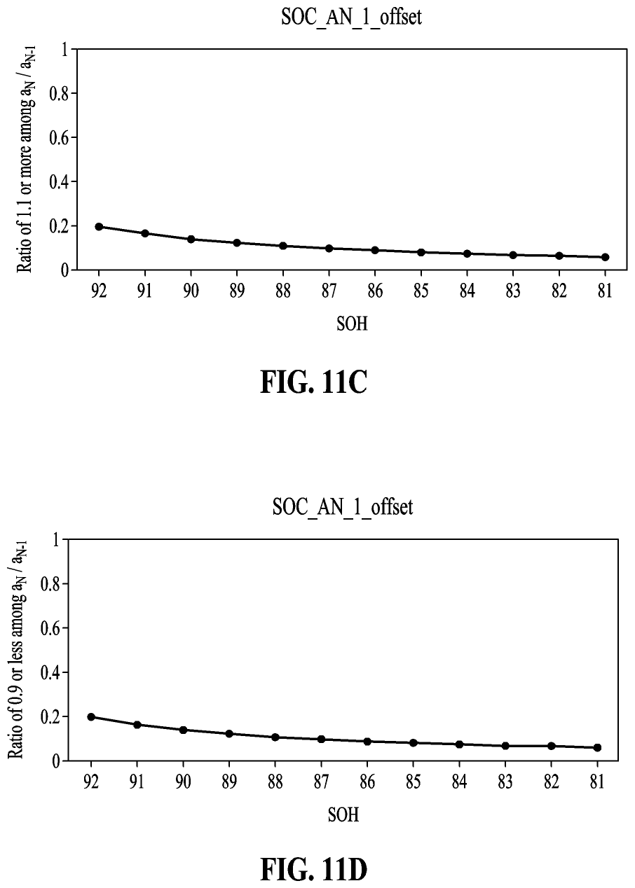

FIG. 11A illustrates an example of absolute values of a gradient that is determined for each of preset SOH sections according to one or more embodiments. Referring to FIG. 11A, in a non-limiting example, a degree of a change of an electrode balance shift for the corresponding SOH section is illustrated.

An absolute value of a gradient for a change of an electrode balance shift associated with each of the SOHs is shown.

FIG. 11B illustrates an example of ratios of a gradient a_{N} for a current SOH section to a gradient a_{N-1} for a previous SOH section based on gradients shown in FIG. 11A according to one or more embodiments.

Referring to FIG. 11B, in a non-limiting example, a gradient ratio for SOH 0.95 may be a ratio between an absolute value of a gradient associated with SOH 0.96 and an absolute value of a gradient associated with SOH 0.95. Because the absolute value of the gradient associated with SOH 0.96 is 0.0078, and the absolute value of the gradient associated with SOH 0.95 is 0.0098, the gradient ratio for SOH 0.95 may be determined to be 1.26.

FIG. 11C illustrates an example of ratios of 1.1 or more among ratios between the gradients shown in FIG. 11B according to one or more embodiments.

Referring to FIG. 11C, in a non-limiting example, among the determined gradient ratios for the SOHs until the SOH of the battery reaches 0.92, a proportion of gradient ratios having a value greater than or equal to the first threshold value (e.g., 1.1) may be calculated as 0.4.

When a current SOH of the battery is determined as the first SOH, an electronic device (e.g., the electronic device 200 of FIG. 2) may calculate a proportion of gradient ratios having a value greater than or equal to the first threshold value (e.g., 1.1) among the determined gradient ratios for the SOHs until the SOH of the battery reaches the first SOH, and determine the type of the first relation function as a function type in which the gradient increases, when the calculated ratio is greater than or equal to a preset value (e.g., 0.7).

FIG. 11D illustrates an example of ratios of 0.9 or less among ratios between the gradients shown in FIG. 11B according to one or more embodiments.

Referring to FIG. 11D, in a non-limiting example, among the determined gradient ratios for the SOHs until the SOH of the battery reaches 0.92, a proportion of gradient ratios having a value less than or equal to the second threshold value (e.g., 0.9) may be calculated as 0.

When a current SOH of the battery is determined as the first SOH, an electronic device (e.g., the electronic device 200 of FIG. 2) may calculate a proportion of gradient ratios having a value less than or equal to the second threshold value (e.g., 0.9) among the determined gradient ratios for the SOHs until the SOH of the battery reaches the first SOH, and determine the type of the first relation function as a function type in which the gradient decreases, when the calculated ratio is greater than or equal to a preset value (e.g., 0.7).

When the type of the first relation function is not determined as the type in which the gradient increases or the gradient decreases, the type of the first relation function may be determined as the function type in which the gradient does not change.

FIG. 12 illustrates an example method of determining an RUL of a battery based on a battery prediction model according to one or more embodiments.

In an example, operation 350 described above with reference to FIG. 3 may include operations 1210 to 1250 to be described hereinafter. Operations 1210 to 1250 may be performed by an electronic device (e.g., the electronic device 200 of FIG. 2).

Referring to FIG. 12, in a non-limiting example, in operation 1210, the electronic device may perform a first simulation on charging and discharging of a battery based on a battery model. The first simulation may be a simulation based on a charging and discharging pattern for the battery. In an example, the first simulation may be a simulation that performs charging and discharging of the battery a preset number of times.

In an example, the electronic device may learn the charging and discharging pattern of a user for the battery, and perform the first simulation based on the learned charging and discharging pattern. In an example, the electronic device may generate the charging and discharging pattern for the battery based on a charge history and a discharge history of the battery. The charge history of the battery may include a battery charging path for fast charging, a battery temperature during charging, and a charging time for one charge, and the like, however, examples are not limited thereto. The discharge history of the battery may include a battery temperature during discharging, an SOC reduction rate per hour, and the like, however, examples are not limited thereto.

In an example, the first simulation of charging and discharging of the battery may be a simulation based on a standard charging and discharging pattern of the battery. In an example, the standard charging and discharging pattern for a product model of a corresponding battery may be generated in advance. The standard charging and discharging pattern may be derived in advance through an experiment or calculation to maximize the RUL of the battery. The standard charging and discharging pattern may be stored in the electronic device. The electronic device may receive the standard charging and discharging pattern from a preset server.

In operation 1220, the electronic device may determine a first predicted cumulative degradation amount of the battery as a result of the first simulation. The description of the method of determining the first cumulative degradation amount of the battery in operation 330 provided above with reference to FIG. 3 may similarly apply to the description of the method of determining the first predicted cumulative degradation amount.

In operation 1230, the electronic device may determine a first predicted value set of one or more parameters based on the first relation function and the first predicted cumulative degradation amount. When the first simulation is performed on the battery, a degree of the change of values of the one or more parameters of the battery may be determined through the first relation function based on the first predicted cumulative degradation amount.

In operation 1240, the electronic device may generate a battery prediction model by updating the battery model based on the first predicted value set of the one or more parameters. The description of the method of updating the battery model in operation 320 provided above with reference to FIG. 3 may similarly apply to the description of the method of generating the battery prediction model.

In operation 1250, the electronic device may determine the RUL of the battery based on the battery prediction model.

In an example, the electronic device may repeatedly perform simulations until a predicted SOH of the battery reaches an end of life (EOL). In an example, the electronic device may repeatedly perform simulations by repeatedly performing operations 1210 to 1240. For example, when one simulation corresponds to 50 charge and discharge cycles and the predicted SOH of the battery reaches the EOL in the 20th simulation, the RUL of the battery may be determined as 1000 charge and discharge cycles.

In an example, the electronic device may receive a target charging and discharging pattern from the user before performing the first simulation. The target charging and discharging pattern may be a condition for the first simulation. In an example, the target charging and discharging pattern may include a battery charge path, a battery temperature during charging, a charging time for one charge, a battery temperature during discharging, and an SOC reduction rate per hour. The results of performing the first simulation performed by different target charging and discharging patterns may be different from each other. For example, the first predicted cumulative degradation amounts of a battery determined as the results of the first simulation may be different from each other. As a result, different RULs of the battery may be determined for different target charging and discharging patterns.

In an example, the electronic device may determine a plurality of RULs of the battery using a plurality of different target charging and discharging patterns. The electronic device may determine a first target charging and discharging pattern corresponding to a longest RUL among the plurality of calculated RULs, as an optimal charging and discharging pattern. The electronic device may suggest using the optimal charging and discharging pattern to the user. In an example, the electronic device may suggest a battery charging path as the optimal charging and discharging pattern to the user. The battery charging path may be defined as a charging limit condition for charging a plurality of charging sections of a battery using different charging currents.

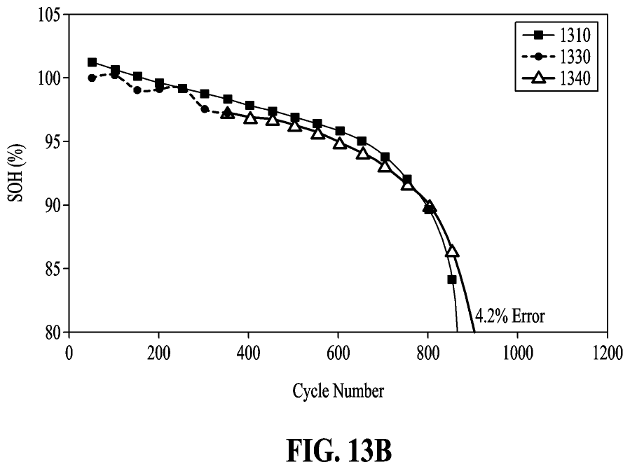

FIG. 13A illustrates an example of a difference between an actual life of a battery and an RUL of the battery estimated using extrapolation according to one or more embodiments.

Referring to FIG. 13A, in a non-limiting example, an error of 159% is obtained between an actual RUL and an RUL of a battery estimated by a method of determining an RUL of a battery using extrapolation to a cumulative degradation amount of the battery measured until the number of charging and discharging cycles of the battery reaches 350.

FIG. 13B illustrates an example of a difference between an actual life of a battery and an RUL of the battery estimated using an electrochemical battery model to which degradation parameters are applied according to one or more embodiments.

Referring to FIG. 13B, in a non-limiting example, an error of 4.2% is obtained between an actual RUL and an RUL of a battery estimated by a method of determining an RUL of a battery using an electrochemical battery model, to which degradation parameters are applied, to a cumulative degradation amount of the battery measured until the number of charging and discharging cycles of the battery reaches 350.

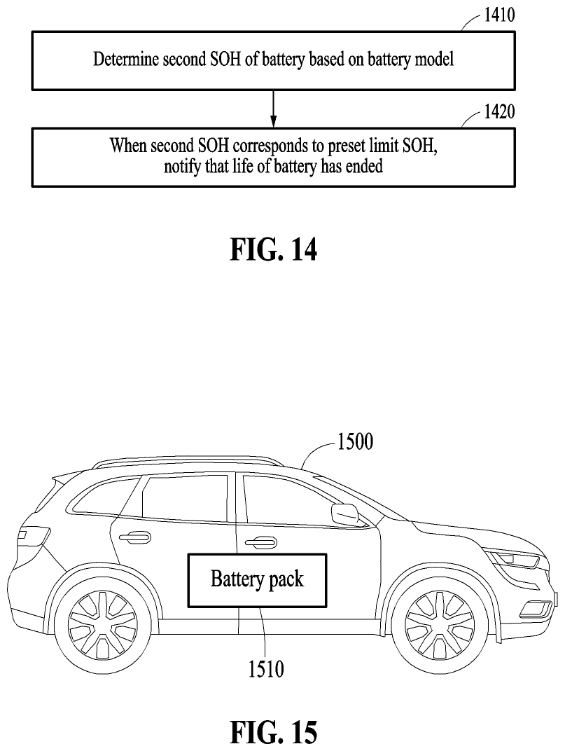

FIG. 14 illustrates an example method of notifying that a life of a battery has ended when a second SOH of the battery corresponds to a limit SOH according to one or more embodiments.

In an example, operations 1410 and 1420 may be performed by an electronic device (e.g., the electronic device 200 of FIG. 2). Operation 1410 may be performed independently of and in parallel with operations 310 to 350 described above with reference to FIG. 3.

Referring to FIG. 14, in a non-limiting example, in operation 1410, the electronic device may determine a second SOH of the battery based on the battery model. In an example, the electronic device may update the battery model to reflect a current value of the degradation parameter, and determine the second SOH of the battery as a current SOH based on the updated battery model.

In operation 1420, when the second SOH corresponds to a preset limit SOH, the electronic device may provide a notification that the life of the battery has ended. In an example, the electronic device may output a notification requesting the user to replace the battery.

FIG. 15 illustrates an example vehicle according to one or more embodiments.

Referring to FIG. 15, in a non-limiting example, a vehicle 1500 includes a battery pack 1510. The vehicle 1500 may be a vehicle using the battery pack 1510 as a power source. The vehicle 1500 may be, for example, an electric vehicle or a hybrid vehicle.

In an example, the battery pack 1510 may include a battery management system (BMS) and battery cells (or battery modules). The BMS may monitor whether the battery pack 1510 shows an abnormality, and prevent over-charging or over-discharging of the battery pack 1510. Further, the BMS may perform thermal control for the battery pack 1510 when the temperature of the battery pack 1510 exceeds a first temperature (for example, 40° C.) or is lower than a second temperature (for example, −10° C.). In addition, the BMS may perform cell balancing so that the battery cells in the battery pack 1510 have balanced charging states.

In an example, the vehicle 1500 may include a battery charging apparatus. The battery charging apparatus may generate a charging path of the battery pack 1510 (or the battery cells in the battery pack 1510), and charge the battery pack 1510 (or the battery cells in the battery pack 1510) using the generated charging path.

In an example, the vehicle 1500 may include a battery management apparatus. The battery management apparatus may determine an RUL of the battery pack 1510 (or the battery cells in the battery pack 1510).

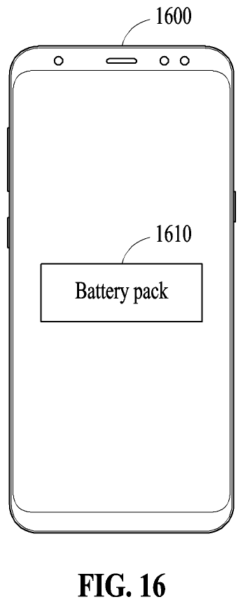

FIG. 16 illustrates an example mobile terminal according to one or more embodiments.

Referring to FIG. 16, in a non-limiting example, a mobile terminal 1600 includes a battery pack 1610. The mobile terminal 1600 may be a device that uses the battery pack 1610 as a power source. The mobile terminal 1600 may be a portable terminal, for example, a smartphone. The battery pack 1610 includes a BMS and battery cells (or battery modules).

In an example, the mobile terminal 1600 may include a battery charging apparatus. The battery charging apparatus may generate a charging path of the battery pack 1610 (or the battery cells in the battery pack 1610), and charge the battery pack 1610 (or the battery cells in the battery pack 1610) using the generated charging path.

In an example, the mobile terminal 1600 may include a battery management apparatus. The battery management apparatus may determine an RUL of the battery pack 1610 (or the battery cells in the battery pack 1610).

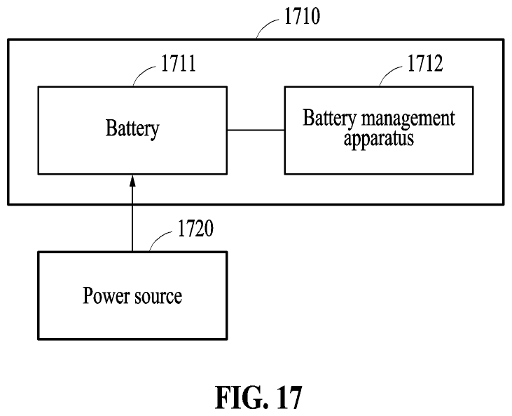

FIG. 17 illustrates an example electronic device according to one or more embodiments.

Referring to FIG. 17, in a non-limiting example, an electronic device 1710 (e.g., the electronic device 200 of FIG. 2) may include a battery 1711 and a battery management apparatus 1712. The electronic device 1710 may be a mobile terminal, such as a smartphone, a laptop, a tablet PC, or a wearable device, but is not limited thereto. The battery management apparatus 1712 may be in the form of an integrated circuit (IC), but is not limited thereto. The battery management apparatus 1712 may determine an RUL of a battery. The electronic device 1710 may receive power from a power source 1720. The battery 1711 may be charged by the power source.

The electronic devices, processors, memories, batteries, battery management apparatuses, battery system 100, battery 110, battery management apparatus 120, electronic device 200, communicator 210, processor 220, memory 230, vehicle 1500, battery pack 1510, mobile terminal 1600, battery pack 1610, electronic device 1710, battery management apparatus 1712, battery 1711, and power source 1720 described herein and disclosed herein described with respect to FIGS. 1-17 are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-17 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method, the method comprising:
updating a battery model indicating an internal state of a battery based on a first value set of one or more parameters indicating a state of the battery;
determining a first cumulative degradation amount of the battery for the first value set;
determining a first relation function based on the first value set and the first cumulative degradation amount; and
determining a remaining useful life (RUL) of the battery based on the first relation function.

2. The method of claim 1, wherein the determining of the first relation function comprises:
determining a first difference set between a previous value set of the one or more parameters and the first value set; and
determining the first relation function based on the first difference set and the first cumulative degradation amount.

3. The method of claim 2, wherein the determining of the first relation function comprises:
determining the first relation function by updating a previous relation function determined based on a previous difference set determined before the first difference set and a previous cumulative degradation amount determined before the first cumulative degradation amount based on the first difference set and the first cumulative degradation amount.

4. The method of claim 1, further comprising:
determining a first state of health (SOH) of the battery for the first value set based on the battery model,
wherein the determining of the RUL of the battery based on the first relation function comprises:
in response to a condition preset in association with the first SOH being satisfied, determining the RUL of the battery based on the first relation function.

5. The method of claim 1, further comprising:
receiving a request for calculating the RUL of the battery,
wherein the determining of the RUL of the battery based on the first relation function comprises:
in response to the request for calculating the RUL of the battery, determining the RUL of the battery based on the first relation function.

6. The method of claim 1, wherein the determining of the RUL of the battery comprises:
performing a first simulation on charging and discharging of the battery based on the battery model;
determining a first predicted cumulative degradation amount of the battery based on a result of the first simulation;
determining a first predicted value set of the one or more parameters based on the first relation function and the first predicted cumulative degradation amount;
generating a battery prediction model by updating the battery model based on the first predicted value set; and
determining the RUL of the battery based on the battery prediction model.

7. The method of claim 6, wherein the first simulation is a simulation based on a charging and discharging pattern for the battery.

8. The method of claim 7, further comprising:
generating the charging and discharging pattern based on a charge history and a discharge history of the battery.

9. The method of claim 6, wherein the first simulation is a simulation based on a standard charging and discharging pattern for the battery.

10. The method of claim 9, further comprising:
receiving the standard charging and discharging pattern from a server.

11. The method of claim 1, further comprising:
determining, using linear regression, a first gradient of a first straight line representing a plurality of first values of a first parameter within a first SOH section of the battery;
determining a second gradient of a second straight line representing a plurality of second values of the first parameter within a second SOH section of the battery using linear regression; and
determining a function type of the first relation function based on the first gradient and the second gradient.

12. The method of claim 11, wherein the determining of the function type of the first relation function comprises:
determining a first ratio of the second gradient to the first gradient; and
determining the function type of the first relation function based on the first ratio.

13. The method of claim 1, further comprising:
determining a second SOH of the battery based on the battery model; and
in response to the second SOH corresponding to a preset limit SOH, providing a notification that the life of the battery has ended.

14. The method of claim 1, wherein the battery is included in a mobile terminal.

15. The method of claim 1, wherein the battery is included in a vehicle.

16. An electronic device, comprising:
processors configured to execute instructions; and
a memory storing the instructions, wherein execution of the instructions configures the processors to:
update a battery model indicating an internal state of a battery based on a first value set of one or more parameters indicating a state of the battery;
determine a first cumulative degradation amount of the battery for the first value set;
determine a first relation function based on the first value set and the first cumulative degradation amount; and
determine a remaining useful life (RUL) of the battery based on the first relation function.

17. The electronic device of claim 16, wherein the processors are further configured to:
determine a first difference set between a previous value set of the one or more parameters and the first value set; and
determine the first relation function based on the first difference set and the first cumulative degradation amount.

18. The electronic device of claim 17, wherein the processors are further configured to:
determine the first relation function by updating a previous relation function determined based on a previous difference set determined before the first difference set and a previous cumulative degradation amount determined before the first cumulative degradation amount based on the first difference set and the first cumulative degradation amount.

19. The electronic device of claim 16, wherein the processors are further configured to:
perform a first simulation on charging and discharging of the battery based on the battery model;
determine a first predicted cumulative degradation amount of the battery as a result of the first simulation;
determine a first predicted value set of the one or more parameters based on the first relation function and the first predicted cumulative degradation amount;
generate a battery prediction model by updating the battery model based on the first predicted value set; and
determine the RUL of the battery based on the battery prediction model.

20. An electronic device, comprising:
processors configured to execute instructions; and
a memory storing the instructions, wherein execution of the instructions configures the processors to:
update a battery model indicating an internal state of a battery based on a first value set of one or more parameters indicating a state of the battery; and
determine a remaining useful life (RUL) of the battery based on a determined a first cumulative degradation amount of the battery for the first value set and a determined first relation function based on the first value set and the first cumulative degradation amount.
